(19) United States
(12) Patent Application Publication
(10) Pub. No.: US 2016/0204340 A1
(43) Pub. Date: Jul. 14, 2016

(54) MAGNETIC MEMORY DEVICE AND METHOD OF MANUFACTURING THE SAME

(71) Applicant: Yoshinori KUMURA, Seoul (KR)

(72) Inventor: Yoshinori KUMURA, Seoul (KR)

(21) Appl. No.: 14/808,282

(22) Filed: Jul. 24, 2015

Related U.S. Application Data
(60) Provisional application No. 62/101,287, filed on Jan. 8, 2015.

(51) Int. Cl. H01L 43/02; H01L 43/10; H01L 43/12; H01L 43/08

(52) U.S. Cl. CPC H01L 43/02; H01L 43/08; H01L 43/10; H01L 43/12

(57) ABSTRACT

According to one embodiment, a method of manufacturing a magnetic memory device, includes forming a lower structure, the lower structure includes a bottom electrode, an interlayer insulating film surrounding the bottom electrode, and a predetermined element containing portion which is in contact with the bottom electrode and which contains a predetermined element other than an element contained in at least a surface area of the bottom electrode and an element contained in at least a surface area of the interlayer insulating film, forming a stack film including a magnetic layer, on the lower structure, forming a hard mask on the stack film, and etching the stack film to expose the predetermined element containing portion.

### CROSS-REFERENCE TO RELATED APPLICATIONS

This application claims the benefit of U.S. Provisional Application No. 62/101,287, filed Jan. 8, 2015, the entire contents of which are incorporated herein by reference.

### FIELD

Embodiments described herein relate generally to a magnetic memory device and a method of manufacturing the same.

### BACKGROUND

A magnetic memory device (semiconductor integrated circuit device) having transistors and magnetoresistive effect elements integrated on a semiconductor substrate has been proposed.

A magnetoresistive effect element has a stack structure formed of a plurality of layers including a magnetic layer. For this reason, the layers (stack films) including the magnetic layer need to be etched to form the stack structure, and the etching is difficult to control.

Thus, a magnetic memory device and a method of manufacturing the same, facilitating control of the etching of the stack films including the magnetic layer are desired.

In addition, the stack structure is formed by etching the layers (stack films) including the magnetic layer by using a hard mask as a mask. In general, when the stack film is etched, the hard mask is also etched. However, the thickness of the hard mask is difficult to detect after the etching.

Thus, a magnetic memory device and a method of manufacturing the same, facilitating detection of the thickness of the hard mask after etching the stack films including the magnetic layer by using the hard mask as a mask have been desired.

### BRIEF DESCRIPTION OF THE DRAWINGS

FIG. 1 is a cross-sectional view illustrating in part a method of manufacturing a magnetic memory device of a first embodiment.

FIG. 2 is a cross-sectional view illustrating in part the method of manufacturing the magnetic memory device of the first embodiment.

FIG. 3 is a cross-sectional view illustrating in part the method of manufacturing the magnetic memory device of the first embodiment.

FIG. 4 is a cross-sectional view illustrating in part the method of manufacturing the magnetic memory device of the first embodiment.

FIG. 5 is a cross-sectional view illustrating in part the method of manufacturing the magnetic memory device of the first embodiment.

FIG. 6 is a cross-sectional view illustrating in part the method of manufacturing the magnetic memory device of the first embodiment.

FIG. 7 is a cross-sectional view illustrating in part the method of manufacturing the magnetic memory device of the first embodiment.

FIG. 8 is a cross-sectional view illustrating in part the method of manufacturing the magnetic memory device of the first embodiment.

FIG. 9 is a cross-sectional view illustrating in part the method of manufacturing the magnetic memory device of the first embodiment.

FIG. 10 is a cross-sectional view illustrating in part the method of manufacturing the magnetic memory device of the first embodiment.

FIG. 11 is a graph showing an SIMS signal intensity of each of Mg and Ta, in the first embodiment.

FIG. 12 is a cross-sectional view illustrating in part a method of manufacturing a magnetic memory device of a second embodiment.

FIG. 13 is a cross-sectional view illustrating in part the method of manufacturing the magnetic memory device of the second embodiment.

FIG. 14 is a cross-sectional view illustrating in part the method of manufacturing the magnetic memory device of the second embodiment.

FIG. 15 is a cross-sectional view illustrating in part the method of manufacturing the magnetic memory device of the second embodiment.

FIG. 16 is a cross-sectional view illustrating in part the method of manufacturing the magnetic memory device of the second embodiment.

FIG. 17 is a cross-sectional view illustrating in part the method of manufacturing the magnetic memory device of the second embodiment.

FIG. 18 is a cross-sectional view illustrating in part the method of manufacturing the magnetic memory device of the second embodiment.

FIG. 19 is a cross-sectional view illustrating in part the method of manufacturing the magnetic memory device of the second embodiment.

FIG. 20 is a graph showing an SIMS signal intensity of each of Mg and Ta, in the second embodiment.

FIG. 21 is a cross-sectional view illustrating in part a method of manufacturing a magnetic memory device of a third embodiment.

FIG. 22 is a cross-sectional view illustrating in part the method of manufacturing the magnetic memory device of the third embodiment.

FIG. 23 is a cross-sectional view illustrating in part the method of manufacturing the magnetic memory device of the third embodiment.

FIG. 24 is a cross-sectional view illustrating in part the method of manufacturing the magnetic memory device of the third embodiment.

FIG. 25 is a cross-sectional view illustrating in part the method of manufacturing the magnetic memory device of the third embodiment.

FIG. 26 is a cross-sectional view illustrating in part the method of manufacturing the magnetic memory device of the third embodiment.

FIG. 27 is a graph showing an SIMS signal intensity of each of Mg and Ta, in the third embodiment.

FIG. 28 is a cross-sectional view illustrating in part a method of manufacturing a magnetic memory device of a fourth embodiment.

FIG. 29 is a cross-sectional view illustrating in part a method of manufacturing the magnetic memory device of the fourth embodiment.

FIG. 30 is a cross-sectional view illustrating in part a method of manufacturing the magnetic memory device of the fourth embodiment.

FIG. 31 is a cross-sectional view illustrating in part a method of manufacturing the magnetic memory device of the fourth embodiment.

FIG. 32 is a cross-sectional view illustrating in part a method of manufacturing the magnetic memory device of the fourth embodiment.

FIG. 33 is a graph showing a monitoring result of an SIMS signal intensity of Mg obtained while etching a stack film in the fourth embodiment.

FIG. 34 is a graph showing secondary ion yields of various elements.

FIG. 35 is an illustration illustrating a structure of a semiconductor integrated circuit device using a magnetoresistive effect element (MTJ element).

### DETAILED DESCRIPTION

In general, according to one embodiment, a method of manufacturing a magnetic memory device, includes: forming a lower structure, the lower structure comprising a bottom electrode, an interlayer insulating film surrounding the bottom electrode, and a predetermined element containing portion which is in contact with the bottom electrode and which contains a predetermined element other than an element contained in at least a surface area of the bottom electrode and an element contained in at least a surface area of the interlayer insulating film; forming a stack film including a magnetic layer, on the lower structure; forming a hard mask on the stack film; and etching the stack film to expose the predetermined element containing portion.

Embodiments will be described hereinafter with reference to the accompanying drawings.

### Embodiment 1

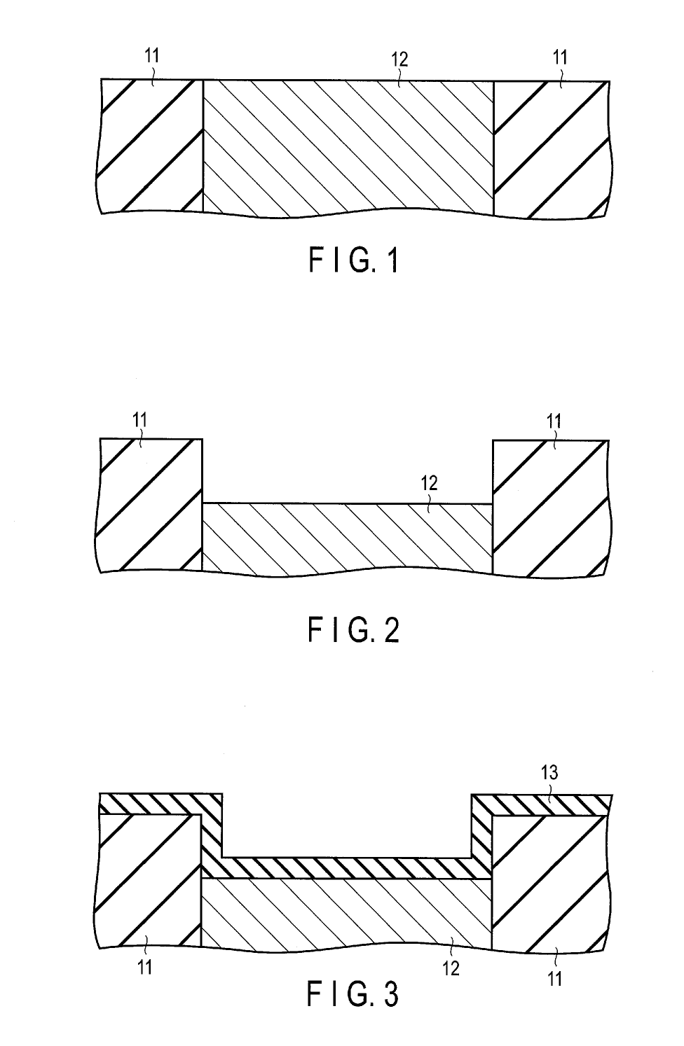

FIG. 1 to FIG. 10 are cross-sectional views illustrating a method of manufacturing a magnetic memory device (semiconductor integrated circuit device) of a first embodiment.

First, as shown in FIG. 1, an interlayer insulating film 11 and a titanium nitride (TiN) film 12 are formed on an underlying area (not shown). The underlying area includes a semiconductor substrate, a transistor, etc. A silicon oxide film or a silicon nitride film is used to form the interlayer insulating film 11. A tungsten (W) film may also be used instead of the TiN film 12.

Next, the TiN film 12 is etched back as shown in FIG. 2. A lower portion 12 of a bottom electrode is thereby formed.

Next, an end-point detection film (predetermined element containing film) 13 is formed on the interlayer insulating film 11 and the TiN film 12 as shown in FIG. 3. More specifically, an MgO film is formed as the end-point detection film 13.

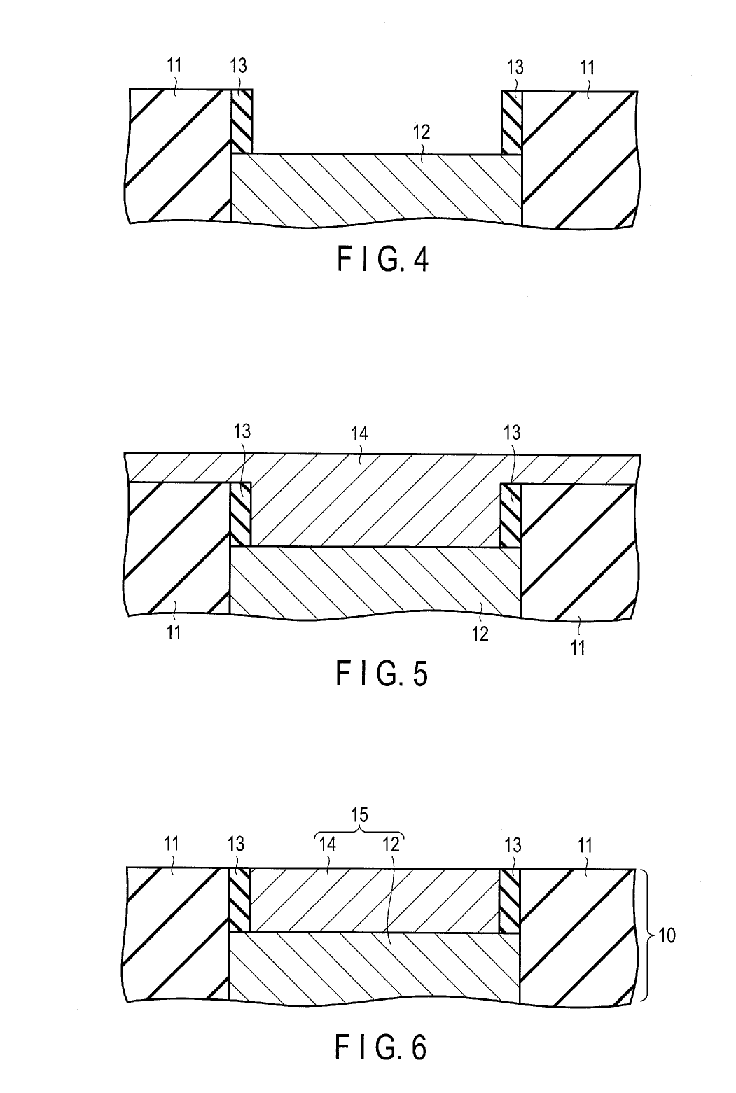

Next, the end-point detection film 13 is etched back and is left on side surfaces alone of the interlayer insulating film 11 as shown in FIG. 4.

Next, a tantalum (Ta) film 14 is formed as an amorphous metal film, on the interlayer insulating film 11, the TiN film 12, and the end-point detection film 13 as shown in FIG. 5.

Next, the Ta film 14 is etched back as shown in FIG. 6. An upper portion 14 of the bottom electrode 15 is thereby formed. The bottom electrode 15 comprises the lower portion 12 formed of the TiN film and the upper portion 14 formed of the Ta film 14.

A lower structure 10 comprising the bottom electrode 15, the interlayer insulating film 11 surrounding the bottom electrode 15, and the end-point detection portion (predetermined element containing portion) 13 which is in contact with the bottom electrode 15, is thus formed as shown in FIG. 6. The end-point detection portion 13 is formed on side surfaces of the upper portion 14 of the bottom electrode 15 to be in contact with the side surfaces of the upper portion 14 of the bottom electrode 15.

The end-point detection portion 13 is used to detect an end point of etching of a stack film 20 to be explained later.

In addition, the end-point detection portion (predetermined element containing portion) 13 contains a predetermined element other than the elements contained in at least a surface area of the bottom electrode 15 and the elements contained in at least a surface area of the interlayer insulating film 11. The predetermined element is preferably a metal element. In the present embodiment, magnesium (Mg) is contained in the end-point detection portion 13 as the predetermined element. In addition, in the present embodiment, the element contained in at least the surface area of the bottom electrode 15 is the element contained in the upper portion 14 of the bottom electrode 15, i.e., tantalum (Ta). In addition, in the present embodiment, the elements contained in at least the surface area of the interlayer insulating film 11 are silicon (Si) and oxygen (O) if the interlayer insulating film 11 is a silicon oxide film, or silicon (Si) and nitrogen (N) if the interlayer insulating film 11 is a silicon nitride film.

In addition, the end-point detection portion (predetermined element containing portion) 13 is preferably formed of an insulating substance. More specifically, the end-point detection portion 13 is preferably formed of an oxide or nitride of a predetermined element.

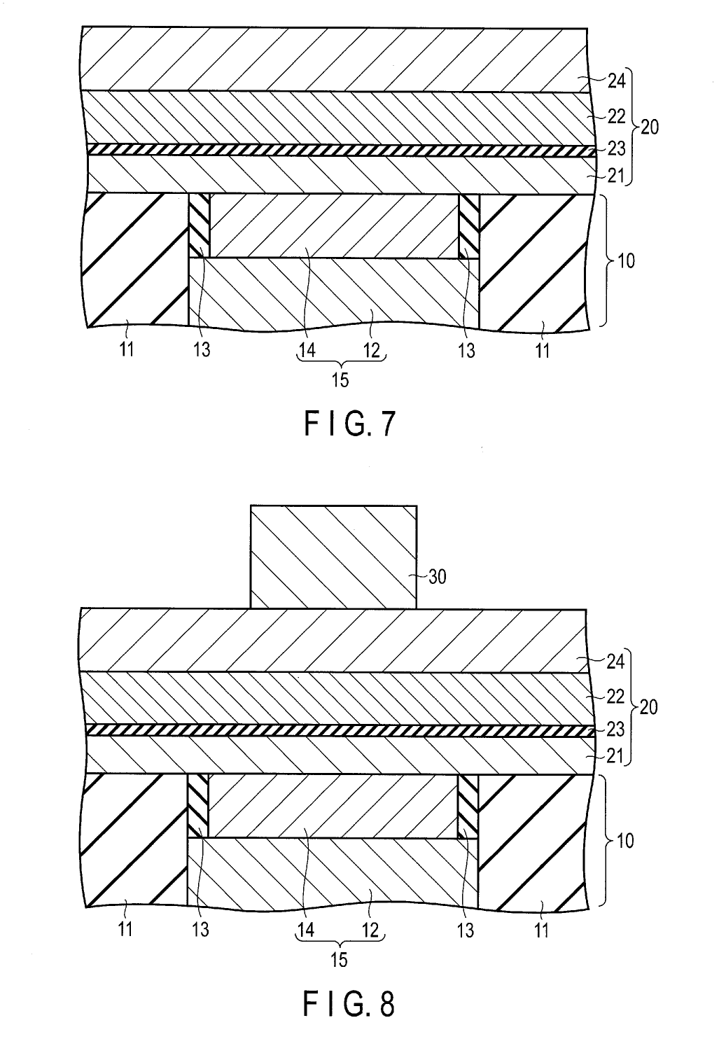

Next, a stack film 20 including a magnetic layer is formed on the lower structure 10 as shown in FIG. 7. More specifically, the stack film 20 includes a storage layer (magnetic layer) 21, a reference layer (magnetic layer) 22, and a tunnel barrier layer (nonmagnetic layer) 23. In the present embodiment, the stack film 20 includes a shift cancelling layer (magnetic layer) 24.

Next, a hard mask 30 is formed on the stack film 20 as shown in FIG. 8. More specifically, after a hard mask film is formed on the stack film 20, the hard mask 30 is formed by processing the hard mask film using a photoresist pattern as a mask.

Next, the stack film 20 is etched by using the hard mask 30 as a mask to expose the end-point detection portion 13, as shown in FIG. 9. As the etching, ion beam etching (IBE) or reactive ion etching (RIE) is employed. When IBE is employed, the etching is executed by means of argon (Ar) ions.

A secondary ion mass spectroscopy (SIMS) signal detector is used to monitor a SIMS signal of a predetermined element (Mg in the present embodiment) contained in the end-point detection portion 13, during the etching of the stack film 20. When the end-point detection portion 13 is exposed by the etching, ions of the predetermined element are detected as secondary ions. After the SIMS signal of the predetermined element is detected, the etching is ended.

The stack film 20a including the magnetic layer is thus formed on the lower structure 10. In the etching step, the stack film 20 may be overetched to control the shape of the stack structure 20a. In this case, the etching is ended after a certain period has elapsed after detection of the SIMS signal of the predetermined element.

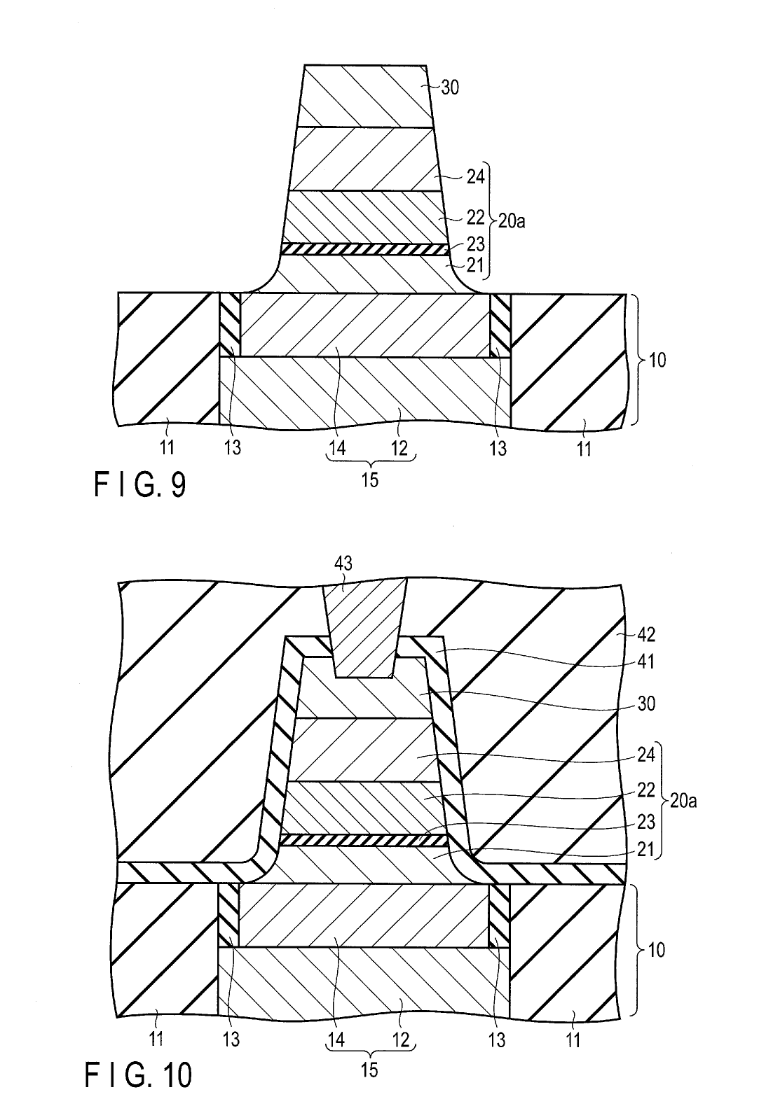

Next, a protective film 41 which covers the stack structure 20a is formed as shown in FIG. 10. A silicon nitride film or an alumina film can be used as the protective film 41. Subsequently, an interlayer insulating film 42 which covers the protective film 41 is formed and the interlayer insulating film 42 is flattened. After that, a hole is formed in the interlayer insulating film 42 and the protective film 41, and a plug (electrode) 43 is formed in the hole.

After that, a magnetic memory device (semiconductor integrated circuit device) shown in FIG. 10 is formed via an interconnect formation step, etc.

A magnetoresistive effect element of a spin transfer torque (STT) type can be obtained by the stack structure 20a. The magnetoresistive effect element is also called a magnetic tunnel junction (MTJ) element. The MTJ element is a magnetic element having perpendicular magnetization. In other words, directions of magnetization of the storage layer 21, the reference layer 22, and the shift cancelling layer 24 are perpendicular to the surface of each of the layers. If the direction of magnetization of the storage layer 21 and the direction of magnetization of the reference layer 22 are parallel to each other, the MTJ element attains a low-resistance state. If the direction of magnetization of the storage layer 21 and the direction of magnetization of the reference layer 22 are antiparallel to each other, the MTJ element attains a high-resistance state. The device can store binary information (0 or 1) in accordance with the low-resistance state or the high-resistance state of the MTJ element. The device can also write the binary information (0 or 1) in accordance with the direction of the current flowing in the MTJ element.

In the manufacturing method of the above-described embodiment, the end point of the etching is detected by monitoring the SIMS signal of the predetermined element (Mg in the present embodiment) contained in the end-point detection portion (predetermined element containing portion) 13 when the stack structure 20a is formed by etching the stack film 20. The end point can be correctly detected with high accuracy and the etching control of the stack film 20 can be easily executed, by the method. Additional explanations will be hereinafter made.

Conventionally, the end point of etching of the stack film has been detected by detecting the SIMS signal of the element (in general, Ta) contained in the surface area of the bottom electrode. However, since SIMS signal intensity of Ta is low, the end point can hardly be correctly detected with high accuracy. In addition, a conductive substance produced by the etching may be redeposited on a side surface of the stack structure and a leak path may be thereby formed, according to the conventional method. In particular, redeposition of Ta contained in the bottom electrode is a major factor of the leak path.

According to the manufacturing method of the present embodiment, the SIMS signal sensitivity can be enhanced and the end point can be correctly detected with high accuracy by using the element having high SIMS signal intensity as the predetermined element contained in the end-point detection portion 13. In addition, since the end point can be correctly detected with high accuracy, a redeposition amount of the etching product on the side surface of the stack structure 20a can be reduced and a leak current can be suppressed.

In the present embodiment, since the end-point detection portion 13 is formed of an insulating substance, conductivity of a redeposited material is low even if a constituent material (MgO, in the present embodiment) of the end-point detection portion 13 is redeposited on the side surface of the stack structure 20a. Therefore, the leak current can also be suppressed from this viewpoint.

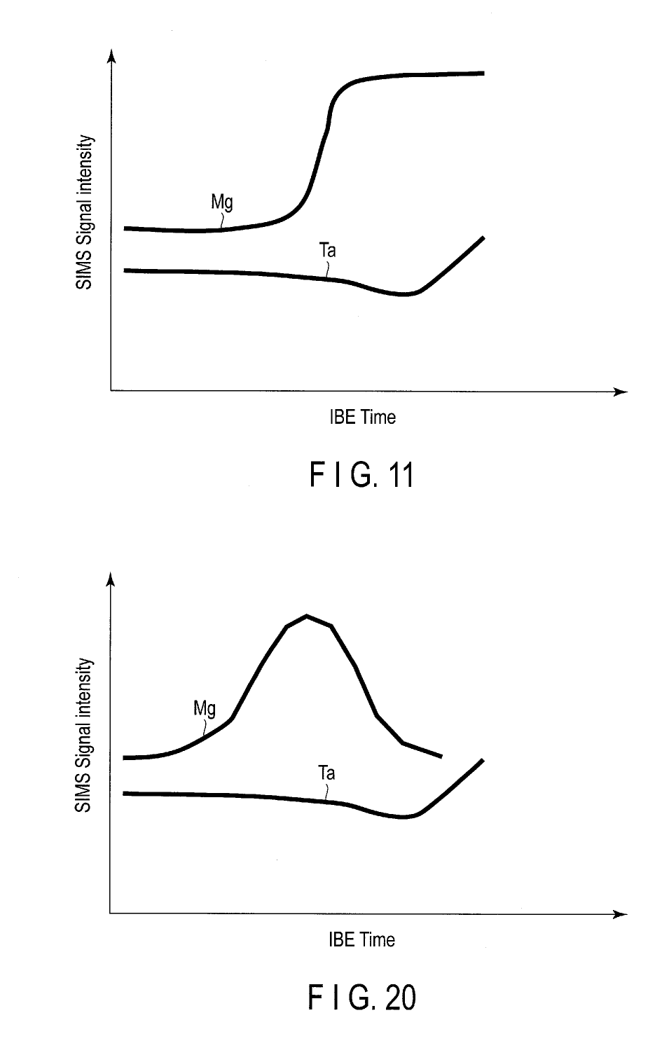

FIG. 11 is a graph showing the SIMS signal intensity of each of Mg and Ta. By exposing the end-point detection portion 13, the SIMS signal intensity of Mg is remarkably increased while the SIMS signal intensity of Ta is low. Therefore, the sensitivity of detection of the SIMS signal can be enhanced by using the element having high SIMS signal intensity such as Mg as the predetermined element contained in the end-point detection portion 13.

In addition, according to the structure of the magnetic memory device of the present embodiment, the leak current flowing between adjacent MTJ elements can be suppressed. Additional explanations on this point will be made here. When the stack film is etched and the stack structure is formed, an etching product may be knocked on and adhere to the surface of the interlayer insulating film 11 and a leak path may be formed. In particular, when a silicon nitride film is used for an uppermost layer of the interlayer insulating film 11, a leak path caused by an etching product becomes a problem. In the present embodiment, since the end-point detection portion 13 formed of an insulating substance (metal oxide) is provided on the side surface of the upper portion 14 of the bottom electrode 15, the leak path between the adjacent MTJ elements can be divided by the end-point detection portion 13. As a result, the leak current flowing between the adjacent MTJ elements can be suppressed in the present embodiment.

### Embodiment 2

Next, a second embodiment will be described. Since basic elements are the same as those of the first embodiment, the descriptions of the elements explained in the first embodiment are omitted.

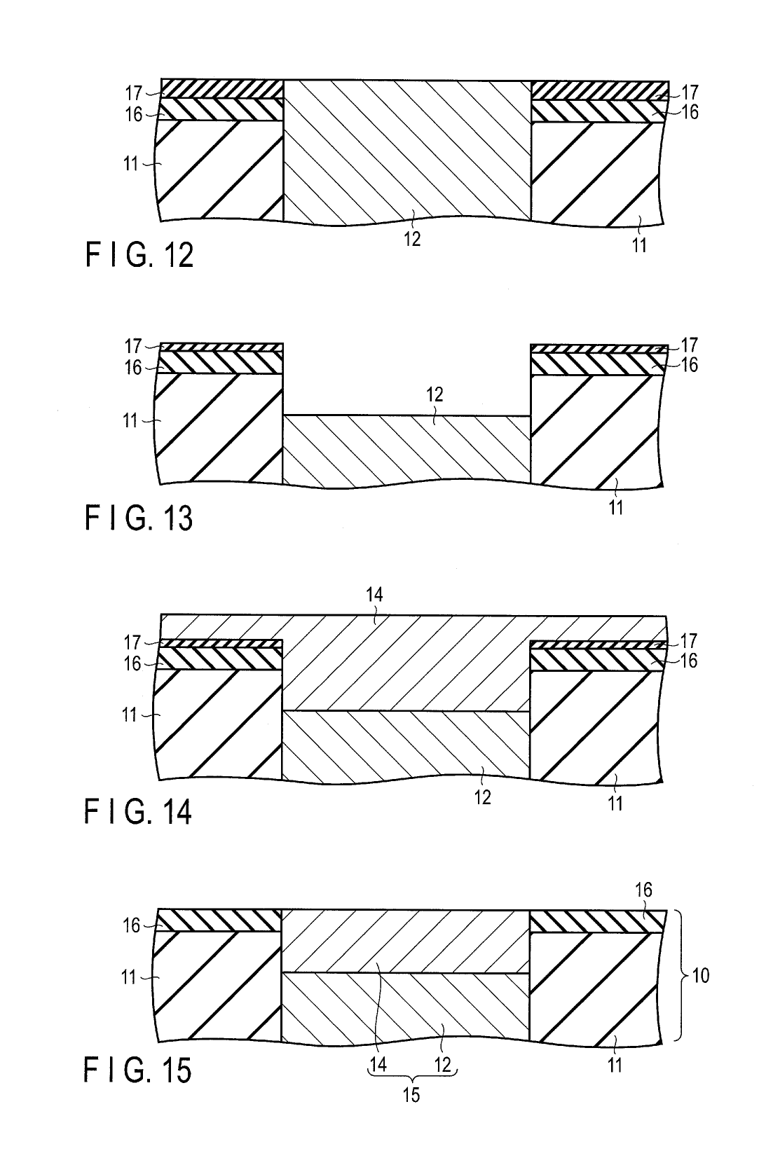

FIG. 12 to FIG. 19 are cross-sectional views illustrating a method of manufacturing a magnetic memory device (semiconductor integrated circuit device) of the second embodiment.

First, as shown in FIG. 12, an interlayer insulating film 11 is formed on an underlying area (not shown). Next, an end-point detection film (predetermined element containing film) 16 is formed on the interlayer insulating film 11. More specifically, an MgO film is formed as the end-point detection film 16. Next, a sacrificial film 17 is formed on the end-point detection film 13. A silicon oxide film is used as the sacrificial film 17. After that, a hole is formed in the interlayer insulating film 11, the end-point detection film 16 and the sacrificial film 17, and a titanium nitride (TiN) film 12 is formed in the hole. A tungsten (W) film may also be used instead of the TiN film 12.

Next, the TiN film 12 is etched back as shown in FIG. 13. A lower portion 12 of a bottom electrode is thereby formed.

Next, a tantalum (Ta) film 14 is formed as an amorphous metal film, on the TiN film 12 and the sacrificial film 17 as shown in FIG. 14.

Next, the Ta film 14 is etched back as shown in FIG. 15. An upper portion 14 of the bottom electrode 15 is thereby formed. The bottom electrode 15 comprises the lower portion 12 formed of the TiN film and the upper portion 14 formed of the Ta film 14. In addition, the sacrificial film 17 is removed, the end-point detection film 16 is exposed, and the end-point detection portion 16 can be obtained, by the etch-back step.

A lower structure 10 comprising the bottom electrode 15, the interlayer insulating film 11 surrounding the bottom electrode 15, and the end-point detection portion (predetermined element containing portion) 16 which is in contact with the bottom electrode 15, is thus formed as shown in FIG. 15. The end-point detection portion 16 is formed on the upper surface of the interlayer insulating film 11 to be in contact with the side surfaces of the upper portion 14 of the bottom electrode 15.

Similarly to the first embodiment, the end-point detection portion (predetermined element containing portion) 16 contains a predetermined element other than the elements contained in at least a surface area of the bottom electrode 15 and the elements contained in at least a surface area of the interlayer insulating film 11. The predetermined element is preferably a metal element. In the present embodiment, magnesium (Mg) is contained in the end-point detection portion 16 as the predetermined element.

Similarly to the first embodiment, the end-point detection portion (predetermined element containing portion) 16 is preferably formed of an insulating substance. More specifically, the end-point detection portion 16 is preferably formed of an oxide or nitride of a predetermined element.

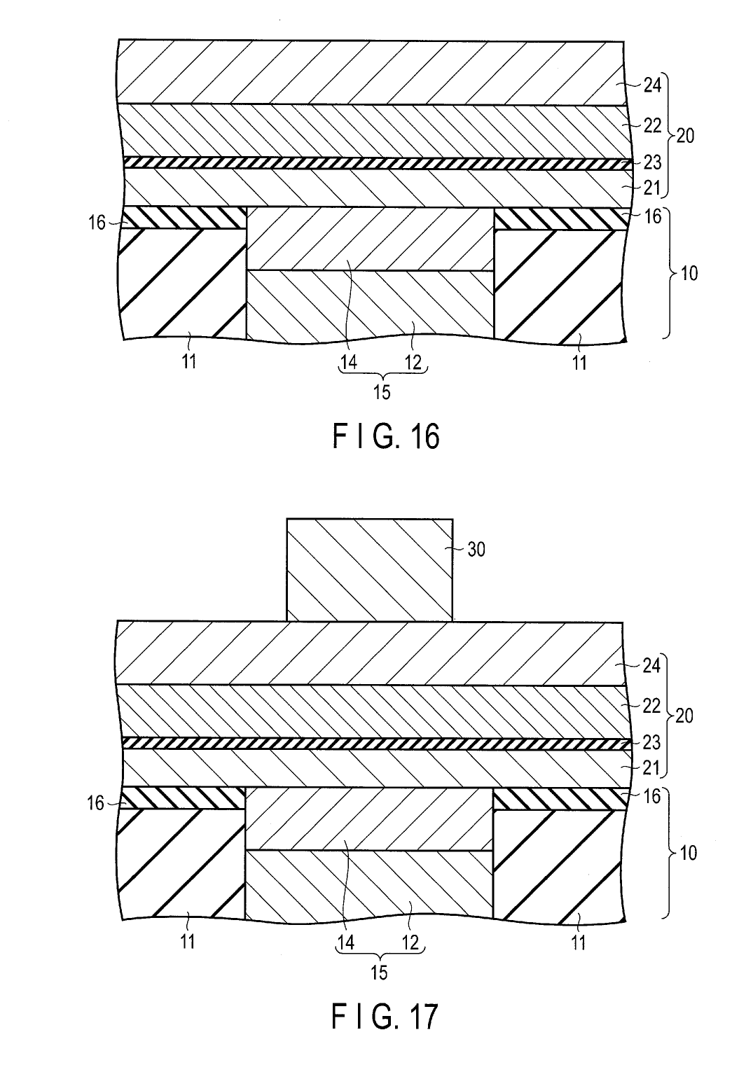

After the lower structure 10 is formed in the step shown in FIG. 15, steps shown in FIG. 16 and FIG. 17 are executed. Since the basic steps shown in FIG. 16 and FIG. 17 are the same as the steps shown in FIG. 7 and FIG. 8 of the first embodiment, explanations are omitted.

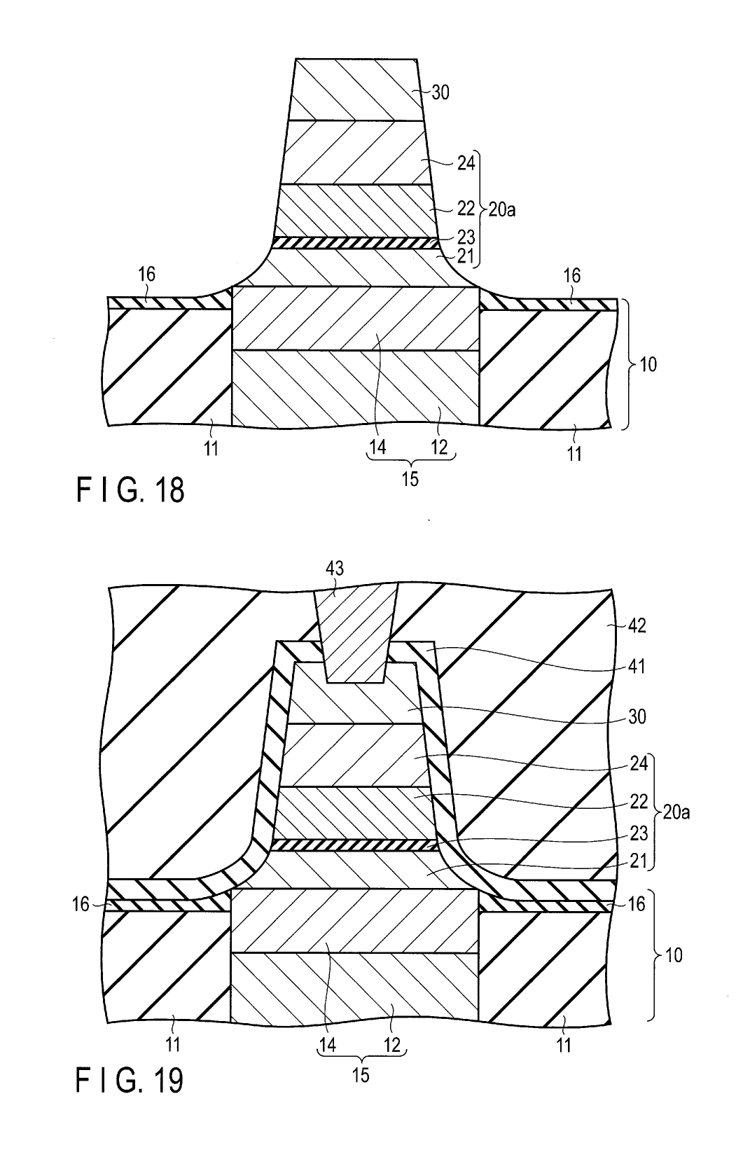

Next, a stack film 20 is etched by using a hard mask 30 as a mask to expose the end-point detection portion 16, as shown in FIG. 18. Similarly to the first embodiment, IBE or RIB is employed for the etching.

A SIMS signal detector is used to monitor a SIMS signal of a predetermined element (Mg in the present embodiment) contained in the end-point detection portion 16, during the etching of the stack film 20. When the end-point detection portion 16 is exposed by the etching, ions of the predetermined element are detected as secondary ions. After the SIMS signal of the predetermined element is detected, the etching is ended.

The stack structure 20a including the magnetic layer is thus formed on the lower structure 10. In the etching step, the stack film 20 may be overetched to control the shape of the stack structure 20a. In this case, the etching is ended after a certain period has elapsed after detection of the SIMS signal of the predetermined element.

After the stack structure 20a is formed in the step shown in FIG. 18, a step shown in FIG. 19 is executed. Since the basic step shown in FIG. 19 is the same as the step shown in FIG. 10 of the first embodiment, explanations are omitted.

After that, a magnetic memory device (semiconductor integrated circuit device) shown in FIG. 19 is formed via an interconnect formation step, etc.

In the manufacturing method of the present embodiment, as described above, the end point of the etching is detected by monitoring the SIMS signal of the predetermined element (Mg in the present embodiment) contained in the end-point detection portion (predetermined element containing portion) 16 when the stack structure 20a is formed by etching the stack film 20. In the present embodiment, too, the end point can be correctly detected with high accuracy and the etching control of the stack film 20 can be easily executed, similarly to the first embodiment. In addition, a leak current caused by redeposition of the etching product on the side surface of the stack structure 20a can be suppressed, similarly to the first embodiment.

FIG. 20 is a graph showing the SIMS signal intensity of each of Mg and Ta. By exposing the end-point detection portion 16, the SIMS signal intensity of Mg is remarkably increased. In FIG. 20, the SIMS signal intensity of Mg reaches a maximum value and then is gradually reduced since the etching continues after the end-point detection portion 16 is exposed. In contrast, the SIMS signal intensity of Ta is low, similarly to the first embodiment. Therefore, the sensitivity of detection of the SIMS signal can be enhanced by using the element having high SIMS signal intensity such as Mg as the predetermined element contained in the end-point detection portion 16.

In the structure of the magnetic memory device of the present embodiment, too, the leak current flowing between adjacent MTJ elements can be suppressed. Additional explanations will be made here. As explained in the first embodiment, when the stack film is etched and the stack structure is formed, an etching product may be knocked on and adhered to the surface of the interlayer insulating film 11 and a leak path may be formed. In particular, when a silicon nitride film is used for an uppermost layer of the interlayer insulating film 11, a leak path caused by an etching product becomes a problem. In the present embodiment, the end-point detection portion 16 formed of an insulating substance (metal oxide) is provided on the upper surface of the interlayer insulating film 11. For this reason, the etching product is oxidized by oxygen in the end-point detection portion 16 and becomes an insulating substance. As a result, the leak current flowing between the adjacent MTJ elements can be suppressed in the present embodiment.

### Embodiment 3

Next, a third embodiment will be described. Since basic elements are the same as those of the first embodiment, the descriptions of the elements explained in the first embodiment are omitted.

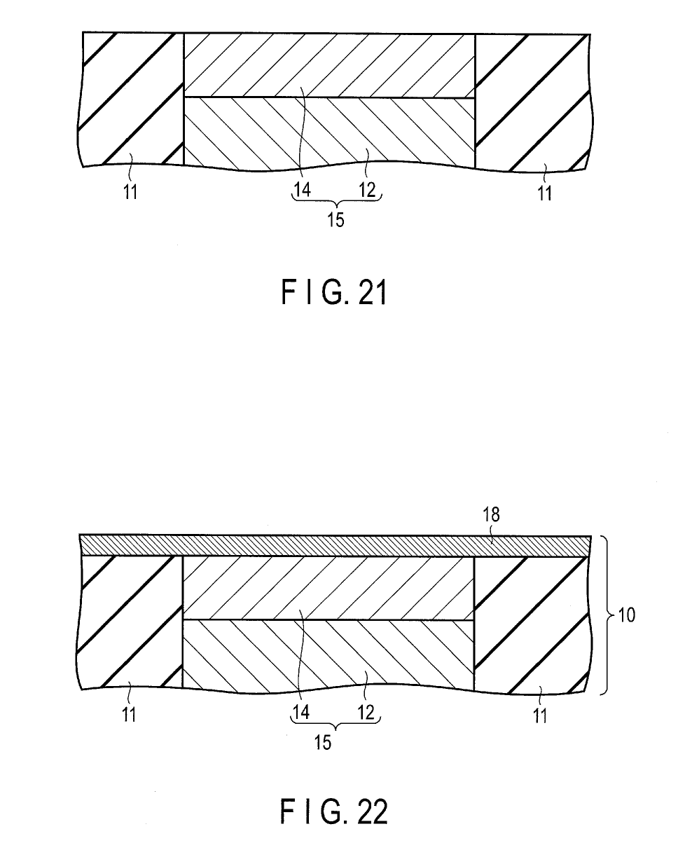

FIG. 21 to FIG. 26 are cross-sectional views illustrating a method of manufacturing a magnetic memory device (semiconductor integrated circuit device) of the third embodiment.

First, as shown in FIG. 21, an interlayer insulating film 11 and a bottom electrode 15 are formed on an underlying area (not shown). Similarly to the first embodiment, a lower portion 12 of the bottom electrode 15 is formed of a TiN film while an upper portion 14 of the bottom electrode 15 is formed of a Ta film 14. The lower portion 12 of the bottom electrode 15 may be formed of a tungsten (W) film.

Next, an end-point detection film (predetermined element containing film) 18 is formed on an interlayer insulating film 11 and the bottom electrode 15 as shown in FIG. 22. More specifically, an Mg film is formed as the end-point detection film 18.

A lower structure 10 comprising the bottom electrode 15, the interlayer insulating film 11 surrounding the bottom electrode 15, and the end-point detection portion (predetermined element containing portion) 18 which is in contact with the bottom electrode 15, is thus formed as shown in FIG. 22. The end-point detection portion 18 is formed on an upper surface of the upper portion 14 of the bottom electrode 15 and an upper surface of the interlayer insulating film 11 to be in contact with the upper surface of the upper portion 14 of the bottom electrode 15.

Similarly to the first embodiment, the end-point detection portion (predetermined element containing portion) 18 contains a predetermined element other than the elements contained in at least a surface area of the bottom electrode 15 and the elements contained in at least a surface area of the interlayer insulating film 11. In the present embodiment, magnesium (Mg) is contained in the end-point detection portion 18 as the predetermined element.

In the present embodiment, the end-point detection portion (predetermined element containing portion) 18 is preferably formed of a conductive substance containing a predetermined element, to retain electric conduction between the bottom electrode 15 and a stack structure 20a which will be explained later. A metal element is preferably used as the predetermined element.

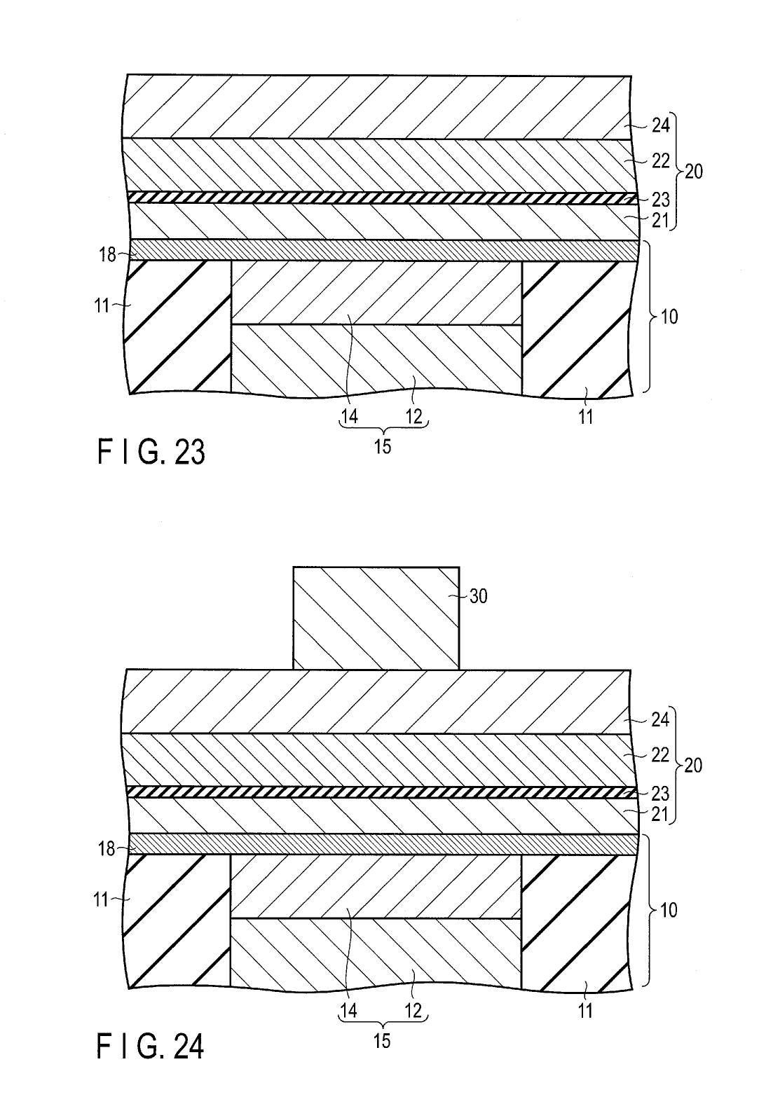

After the lower structure 10 is formed in the step shown in FIG. 22, steps shown in FIG. 23 and FIG. 24 are executed. Since the basic steps shown in FIG. 23 and FIG. 24 are the same as the steps shown in FIG. 7 and FIG. 8 of the first embodiment, explanations are omitted.

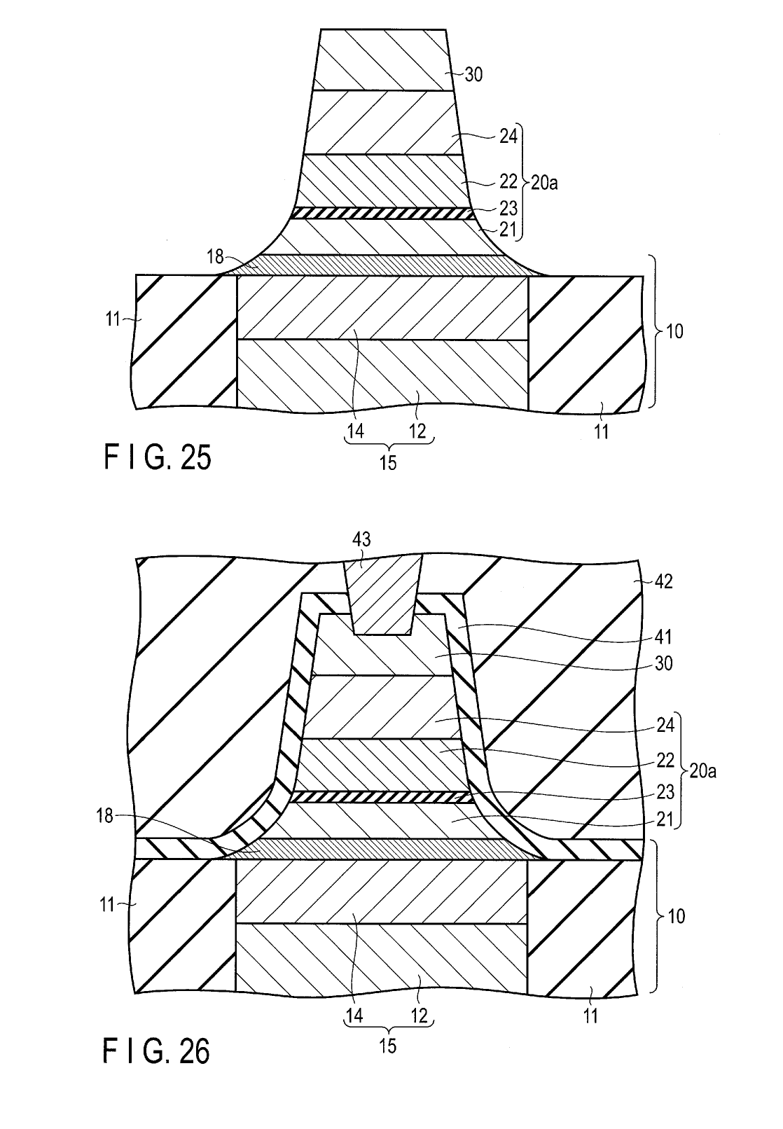

Next, a stack film 20 is etched by using a hard mask 30 as a mask to expose the end-point detection portion 18, as shown in FIG. 25. Similarly to the first embodiment, IBE or RIE is employed for the etching.

A SIMS signal detector is used to monitor a SIMS signal of a predetermined element (Mg in the present embodiment) contained in the end-point detection portion 18, during the etching of the stack film 20. When the end-point detection portion 18 is exposed by the etching, ions of the predetermined element are detected as secondary ions. After the SIMS signal of the predetermined element is detected, the etching is ended.

The stack structure 20a including the magnetic layer is thus formed on the lower structure 10. In the etching step, the stack film 20 is overetched to control the shape of the stack structure 20a and to remove the end-point detection portion 18 on the interlayer insulating film 11. In this case, the etching is ended after a certain period has elapsed after detection of the SIMS signal of the predetermined element.

After the stack structure 20a is formed in the step shown in FIG. 25, a step shown in FIG. 26 is executed. Since the basic step shown in FIG. 26 is the same as the step shown in FIG. 10 of the first embodiment, explanations are omitted.

After that, a magnetic memory device (semiconductor integrated circuit device) shown in FIG. 26 is formed via an interconnect formation step, etc.

In the manufacturing method of the present embodiment, as described above, the end point of the etching is detected by monitoring the SIMS signal of the predetermined element (Mg in the present embodiment) contained in the end-point detection portion (predetermined element containing portion) 18 when the stack structure 20a is formed by etching the stack film 20. In the present embodiment, too, the end point can be correctly detected with high accuracy and the etching control of the stack film 20 can be easily executed, similarly to the first embodiment. In addition, a leak current caused by redeposition of the etching product on the side surface of the stack structure 20a can be suppressed, similarly to the first embodiment.

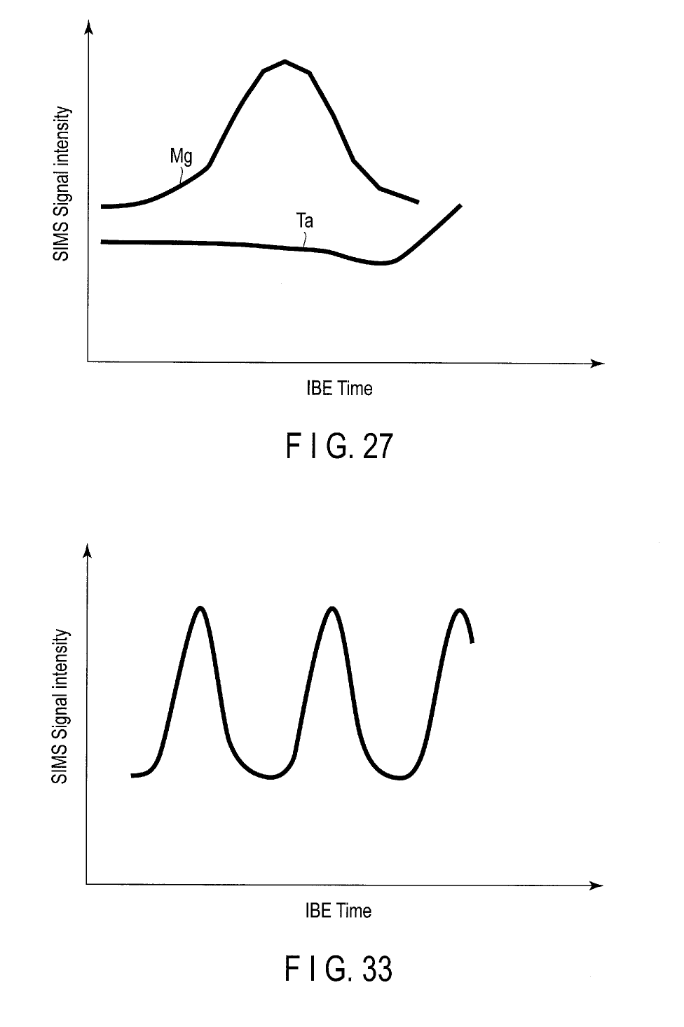

FIG. 27 is a graph showing the SIMS signal intensity of each of Mg and Ta. By exposing the end-point detection portion 18, the SIMS signal intensity of Mg is remarkably increased. In FIG. 27, the SIMS signal intensity of Mg reaches a maximum value and then is gradually reduced since the etching continues after the end-point detection portion 18 is exposed. In contrast, the SIMS signal intensity of Ta is low, similarly to the first embodiment. Therefore, the sensitivity of detection of the SIMS signal can be enhanced by using the element having high SIMS signal intensity such as Mg as the predetermined element contained in the end-point detection portion 18.

### Embodiment 4

Next, a fourth embodiment will be described. The descriptions of the elements explained in the first embodiment are omitted.

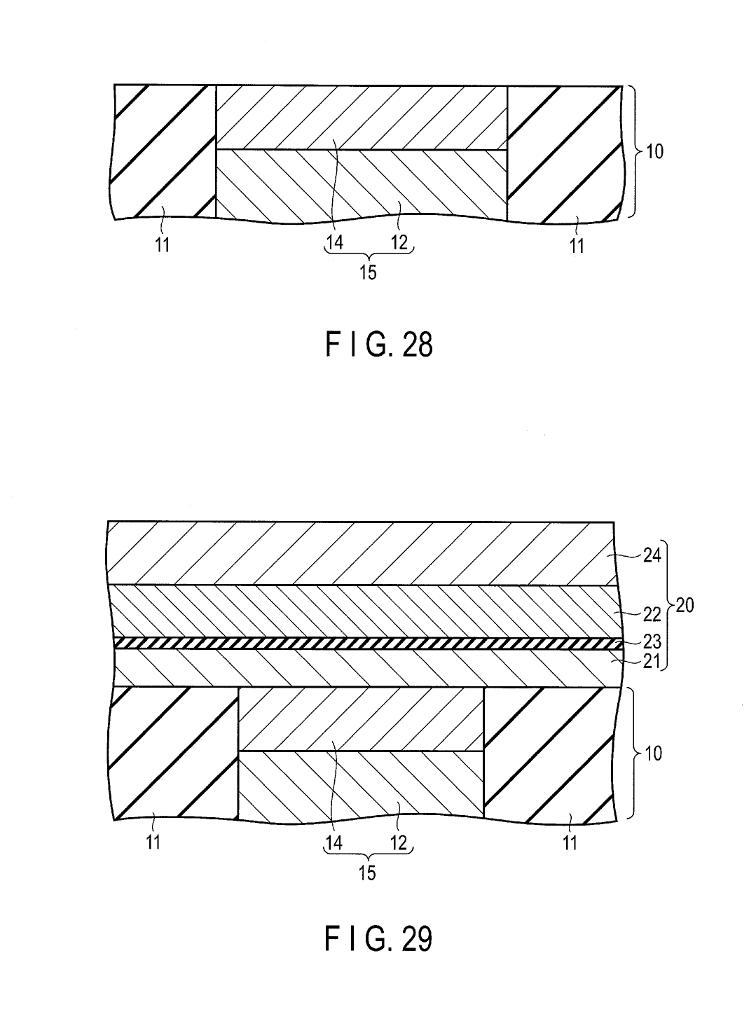

FIG. 28 to FIG. 32 are cross-sectional views illustrating a method of manufacturing a magnetic memory device (semiconductor integrated circuit device) of the fourth embodiment.

First, as shown in FIG. 28, an interlayer insulating film 11 and a bottom electrode 15 are formed on an underlying area (not shown). Similarly to the first embodiment, a lower portion 12 of the bottom electrode 15 is formed of a TiN film while an upper portion 14 of the bottom electrode 15 is formed of a Ta film 14. The lower portion 12 of the bottom electrode 15 may be formed of a tungsten (W) film. A lower structure 10 comprising the bottom electrode 15 and the interlayer insulating film 11 surrounding the bottom electrode 15 is formed in this step.

Next, a stack film 20 is formed on the lower structure 10 as shown in FIG. 29. Since the step forming the stack film 20 is the same as the step shown in FIG. 7 of the first embodiment, explanations are omitted.

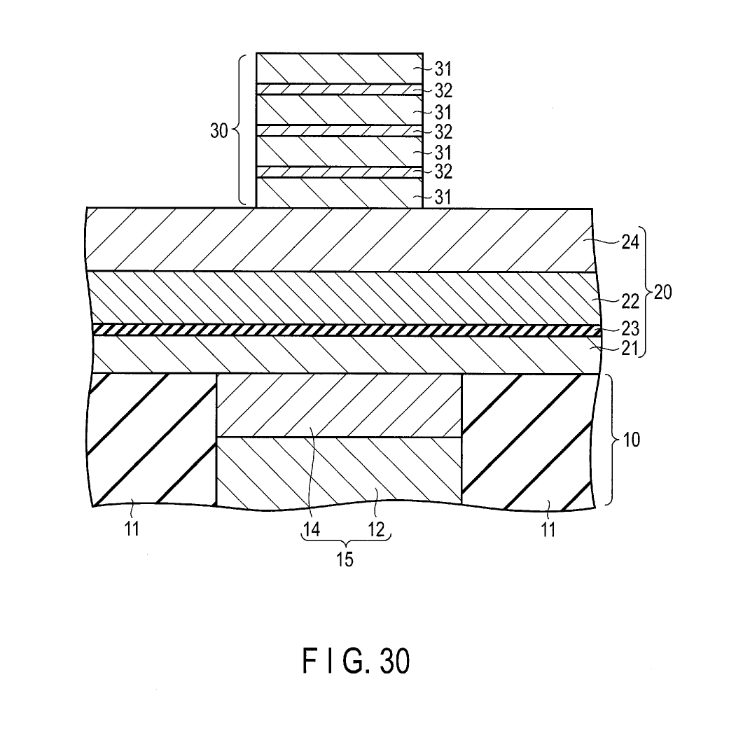

Next, a hard mask 30 is formed on the stack film 20 as shown in FIG. 30. More specifically, after a hard mask film is formed on the stack film 20, the hard mask 30 is formed by processing the hard mask film using a photoresist pattern as a mask.

In the structure of the hard mask 30, in the present embodiment, at least two hard mask material layers 31, and at least one predetermined element containing layer 32 containing a predetermined element other than elements contained in the at least two hard mask material layers 31 are alternately stacked. The hard mask 30 is formed of a conductive substance. In other words, the hard mask material layers 31 and the predetermined element containing layer 32 are formed of conductive materials. The hard mask material layers 31 and the predetermined element containing layer 32 are preferably formed of metal.

In the present embodiment, the hard mask material layers 31 are formed of tungsten (W). The predetermined element containing layer 32 contains magnesium (Mg) as the predetermined element. More specifically, the predetermined element containing layer 32 is formed of Mg layers.

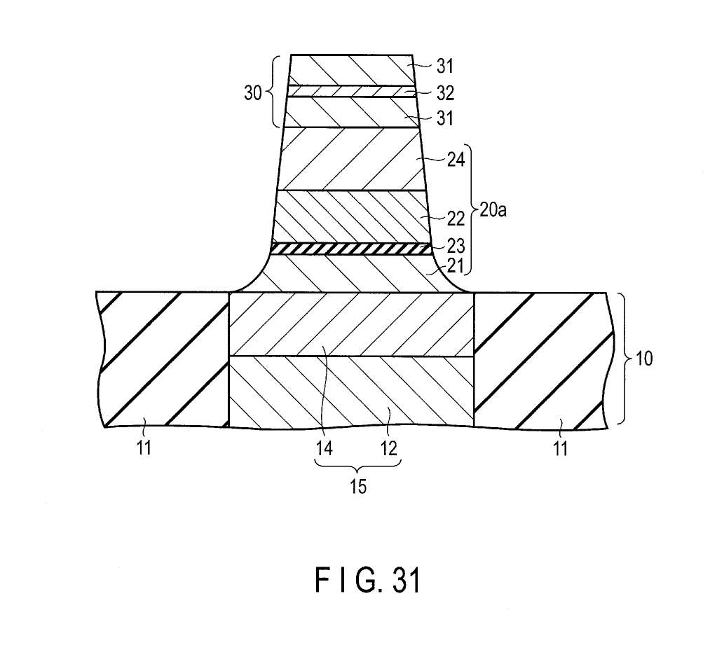

Next, the stack film 20 is etched by using the hard mask 30 as a mask as shown in FIG. 31. Similarly to the first embodiment, IBE or RIE is employed for the etching. The hard mask 30 is also etched and becomes thinner during the etching of the stack film 20. For this reason, the at least one predetermined element containing layer 32 is exposed during the etching of the stack film 20.

A SIMS signal detector is used to monitor a SIMS signal of a predetermined element (Mg in the present embodiment) contained in the predetermined element containing layer 32, during the etching of the stack film 20. When the predetermined element containing layer 32 is exposed by the etching, ions of the predetermined element are detected as secondary ions.

FIG. 33 is a graph showing a result of monitoring the SIMS signal intensity of Mg during the etching of the stack film 20. As shown in FIG. 33, a peak of the SIMS signal intensity of Mg is detected every time the predetermined element containing layer 32 is exposed. A degree of etching of the hard mask 30 can be therefore detected by counting the number of peaks of the SIMS signal intensity after the etching of the stack film 20 has been ended. In other words, a thickness of the hard mask 30 can be detected after the stack film 20 is etched.

In the etching step shown in FIG. 31, the stack structure 20a including the magnetic layer is formed on the lower structure 10.

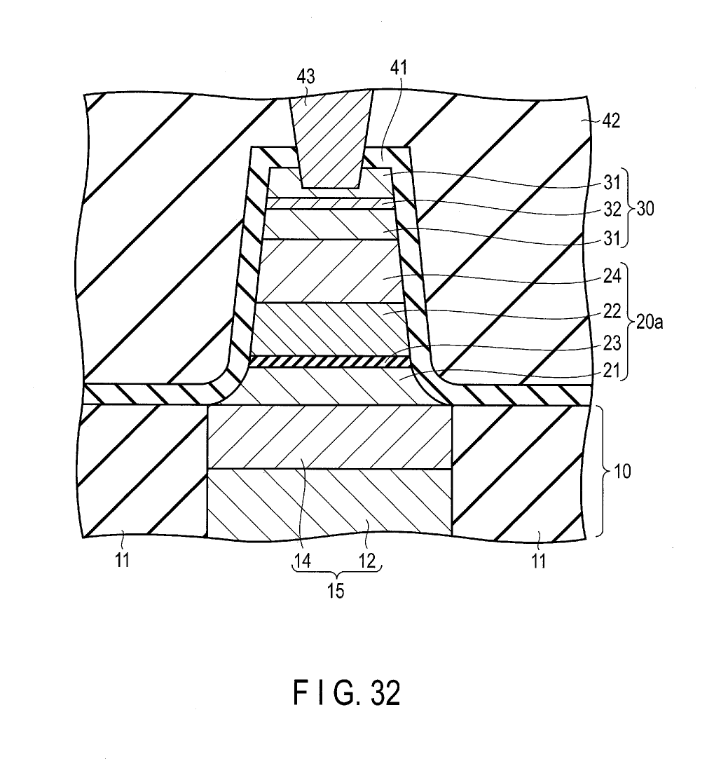

Next, a protective film 41 which covers the stack structure 20a is formed as shown in FIG. 32. A silicon nitride film or an alumina film can be used as the protective film 41. Subsequently, an interlayer insulating film 42 which covers the protective film 41 is formed and the interlayer insulating film 42 is flattened. After that, a hole is formed in the interlayer insulating film 42 and the protective film 41, and a plug (electrode) 43 is formed in the hole. When the hole is formed in the interlayer

Insulating film 42 and the protective film 41 in the step shown in FIG. 32, a part of the hole is generally formed in the hard mask 30. For this reason, the degree of etching is desirably controlled in accordance with the thickness of the hard mask 30 when the hole is formed. In other words, when the hard mask 30 is thin, reducing the etching amount and making the hole shallower are preferable. In contrast, when the hard mask 30 is thick, increasing the etching amount and making the hole deeper are preferable.

In the present embodiment, the thickness of the hard mask 30 to be obtained after the etching step shown in FIG. 31 has been ended can be detected by monitoring the SIMS signal of the predetermined element in the etching step shown in FIG. 31. Thus, the thickness of the hard mask can be correctly recognized at the formation of the hole in the interlayer insulating film 42 and the protective film 41, and the degree of etching can be correctly controlled at the formation of the hole.

After the step shown in FIG. 32 is ended, a magnetic memory device (semiconductor integrated circuit device) shown in FIG. 32 is formed via an interconnect formation step, etc.

In the manufacturing method of the present embodiment, as described above, the thickness of the hard mask 30 to be obtained after the etching of the stack film 20 can be recognized by monitoring the SIMS signal of the predetermined element (Mg in the present embodiment) contained in the predetermined element containing layer 32 during the etching of the stack film 20 and formation of the stack structure 20a. As a result, for example, since the thickness of the hard mask can be correctly recognized at the formation of the hole in the interlayer insulating film 42 and the protective film 41, the degree of etching can be correctly controlled at the formation of the hole.

In addition, variation in an etching rate of the hard mask 30 can also be recognized by recognizing a cycle of peaks of the SIMS signal intensity shown in FIG. 33. By feeding back an etching rate of the hard mask 30 to a subsequent lot, an etching time of the subsequent lot can be correctly adjusted.

At least one predetermined element containing layer 32 may be provided in the present embodiment, but at least two predetermined element containing layers 32 may preferably be provided.

In the first to fourth embodiments, magnesium (Mg) is used as the predetermined element contained in the end point detected portion (predetermined element containing portion) and the predetermined element containing layer, but an element other than magnesium (Mg) can also be used.

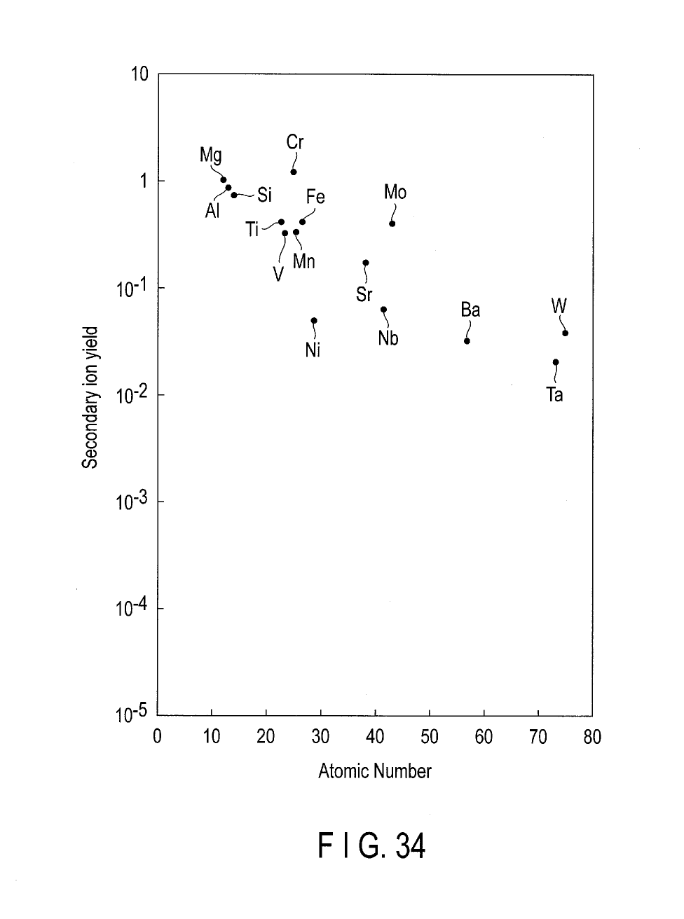

FIG. 34 is a graph showing secondary ion yields (number of secondary ions/number of primary ions) of various elements. As shown in FIG. 34, the secondary ion yield of each of magnesium (Mg), aluminum (Al), titanium (Ti), vanadium (V), chromium (Cr), manganese (Mn), iron (Fe), nickel (Ni), strontium (Sr), niobium (Nb), molybdenum (Mo), barium (Ba), tungsten (W), etc. Is higher than that of tantalum (Ta) that is a typical bottom electrode material. The SIMS signal intensity can be therefore made higher by using the elements as the predetermined elements. Alternatively, a silicon oxide doped with boron (B), which is the predetermined element, may also be used. Furthermore, when a material other than tantalum is used as the bottom electrode material, the predetermined elements can be used.

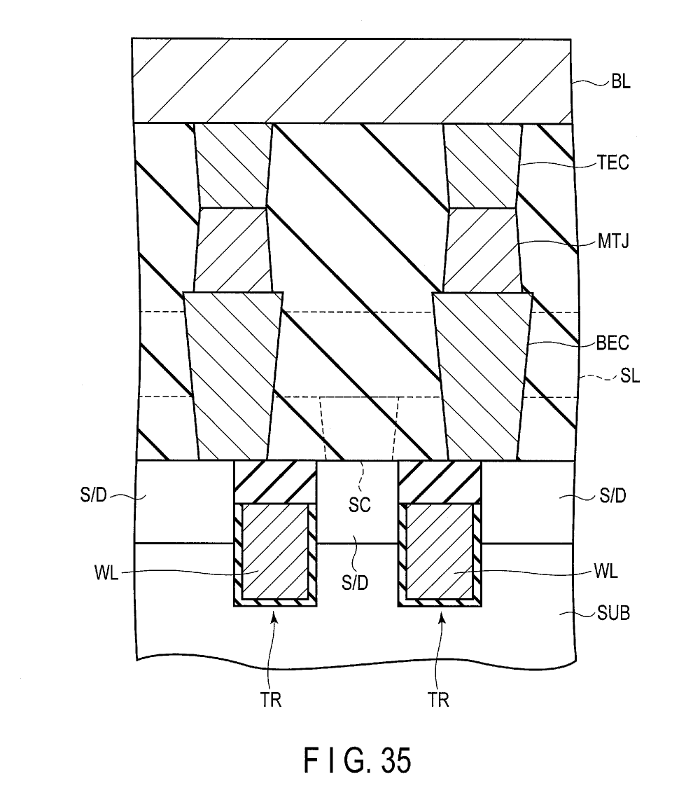

FIG. 35 pictorially shows the structure of the semiconductor integrated circuit device for which the magnetoresistive effect element (MTJ element) explained in the first to fourth embodiments is used.

A buried-gate type MOS transistor TR is formed in a semiconductor substrate SUB. A gate electrode of the MOS transistor TR functions as a word line WL. In the MOS transistor TR, a bottom electrode BEC is connected to one of source/drain areas S/D and a source line contact SC is connected to the other of the source/drain areas S/D.

The magnetoresistive effect element MTJ is formed on the bottom electrode BEC, and a top electrode TEC is formed on the magnetoresistive effect element MTJ. A bit line BL is connected to the top electrode TEC. A source line SL is connected to the source line contact SC.

An excellent semiconductor integrated circuit device can be obtained by applying the structure and method explained in the first to fourth embodiments to the semiconductor integrated circuit device shown in FIG. 35.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1-18. (canceled)

19. A magnetic memory device comprising:
a lower structure comprising a bottom electrode and an interlayer insulating film surrounding the bottom electrode;
a stack structure which is formed on the lower structure and which includes a magnetic layer; and
an upper structure which is formed on the stack structure and in which at least one first layer, and at least one second layer containing a predetermined element other than an element contained in the at least one first layer are alternately stacked.

20. The device of claim 19, wherein the predetermined element is selected from magnesium (Mg), aluminum (Al), titanium (Ti), vanadium (V), chromium (Cr), manganese (Mn), iron (Fe), nickel (Ni), strontium (Sr), niobium (Nb), molybdenum (Mo), barium (Ba) and tungsten (W).

21. The device of claim 19, wherein the at least one second layer is formed of a conductive material.

22. The device of claim 19, wherein an uppermost layer of the upper structure is formed of one of the at least one first layer.

23. The device of claim 19, wherein a lowermost layer of the upper structure is formed of one of the at least one first layer.

24. The device of claim 19, wherein the upper structure comprises one of the at least one first layer, one of the at least one second layer, and another one of the at least one first layer, which are stacked in that order.

25. The device of claim 19, wherein one of the at least one first layer is thicker than one of the at least one second layer.

26. The device of claim 19, further comprising a protective film which covers the stack structure and the upper structure.

27. The device of claim 26, further comprising a plug which includes a portion formed in the protective film.

28. The device of claim 27, wherein the plug is in contact with an uppermost one of the at least one first layer.

29. The device of claim 19, wherein the at least one first layer comprises a plurality of first layers having a same thickness.

30. The device of claim 19, wherein the at least one second layer comprises a plurality of second layers having a same thickness.
